(19) United States
(12) Patent Application Publication
(10) Pub. No.: US 2025/0158609 A1
(43) Pub. Date: May 15, 2025

(54) LOOK AHEAD CLOCK GATING

(71) Applicant: STMicroelectronics International N.V., Geneva (CH)

(72) Inventors: John Kevin MOORE, Edinburgh (GB); Kenneth DARGAN, Edinburgh (GB); Angeliki DELAKOURA, Edinburgh (GB)

(73) Assignee: STMicroelectronics International N.V., Geneva (CH)

(21) Appl. No.: 18/541,034

(22) Filed: Dec. 15, 2023

(30) Foreign Application Priority Data
Nov. 10, 2023 (GR) 20230100935

(51) Int. Cl. H03K 17/51; G01S 7/484; H01S 5/042; H03K 3/037; H03K 5/00; H03K 5/131; H03K 5/1534; H03K 19/00; H03K 19/20

(52) U.S. Cl. CPC H03K 17/51; G01S 7/484; H01S 5/042; H03K 3/037; H03K 5/131; H03K 5/1534; H03K 19/0016; H03K 19/20; H03K 2005/00234

(57) ABSTRACT

First digital-components are clocked by a system-clock, and second digital-components are clocked by a gated system-clock. A detection-module identifies detection-events and generates an event-flag in response. A digital-comparator generates a comparator-output based upon comparison of a count-value with a threshold, the comparator-output asserted when the count-value is less than the threshold and is deasserted when the count-value is equal-to or greater-than the threshold. A counter sets the count-value to a predetermined-value upon receipt of the event-flag, and, in response to assertion of the comparator-output, increments the count-value upon each successive rising-edge of the system-clock, but ceases when the comparator-output is deasserted. A clock-gating module releases gating of the gated system-clock so it follows the system-clock, a first number of cycles of the system-clock after assertion of the comparator-output, and reinstates gating of the gated system-clock a second number of cycles of the system-clock after the release of the gating.

### PRIORITY CLAIM

This application claims the priority benefit of Greek Application for patent No. 20230100935, filed on Nov. 10, 2023, the content of which is hereby incorporated by reference in its entirety to the maximum extent allowable by law.

### TECHNICAL FIELD

This disclosure is related to the field of distance sensing, and, in particular, to a clock gating scheme for clocking parts of the digital pipeline of a time-of-flight (TOF) ranging system when there is TOF data to be processed, but to otherwise not clock said parts of the digital pipeline of the TOF ranging system.

### BACKGROUND

Time-of-Flight (TOF) sensors are components utilized within various advanced technologies, playing a role in accurately measuring distances to targets. Applications for such TOF sensors span across multiple technical areas, including autonomous navigation for vehicles and drones, 3D mapping and imaging, virtual and augmented reality systems, gesture recognition in consumer electronics, and facial recognition in consumer electronics.

There are two primary variants of TOF technology: Direct Time-of-Flight (dTOF) sensors and Indirect Time-of-Flight (iTOF) sensors.

A dTOF sensor operates by emitting a short pulse of light towards a target and measuring the time it takes for the light to reflect off the target and return to the sensor. This approach yields an accurate measure of the distance to the target. dTOF technology generally offers longer range capabilities and superior performance in high ambient light conditions. The ability of dTOF sensors to filter out ambient contributions based on the phase of light arrival is a distinguishing feature that enhances its performance in these settings.

On the other hand, an iTOF sensor operates by emitting a continuous wave of modulated light and measuring the phase shift between the emitted and the reflected light waves. A distinguishing characteristic of iTOF sensors is their ability to determine distances greater than twice the distance light would travel in free space during one optical pulse duration. To achieve this, iTOF sensors employ multiple pulse periods, varying the duration and frequency of emitted pulses to differentiate and resolve overlapping signals that might be ambiguous.

The phase differences between emitted and reflected light are translated into specific histogram bins. Each bin in the histogram corresponds to a specific time interval, capturing the count of measurements that fall within that interval. Photodiode-based iTOF systems tend to use a small number of such bins, with this limited number of bins aiding in simplifying the processing and readout but potentially constraining the resolution of time-of-flight measurements.

While iTOF sensors can measure distances, they are generally less precise than dTOF sensors, particularly over longer ranges or in brightly lit environments. However, the analog readout in iTOF sensors allows for a large array of iTOF pixels, offering superior x/y resolution, albeit at the expense of z/ambient performance. The power efficiency and reduced production costs of iTOF sensors make them apt for high-resolution array applications. Very low-cost single point sensors are typically based on Single Photon Avalanche Diode (SPAD) technology.

A dTOF sensor 10 is now described with reference to FIG. 1. The dTOF sensor 10 is embodied within a housing 11 that is partitioned into two chambers separated by an optical barrier 14: an outgoing chamber 12 and an incoming chamber 13.

Within the outgoing chamber 12, a Vertical-Cavity Surface-Emitting Laser (VCSEL) substrate 15 houses the VCSEL 16. The majority of the infrared laser beam produced by the VCSEL 16 forms an outgoing beam 17 directed towards a target object, while a portion of the infrared laser beam produced by the VCSEL 16 bounces off the interior of the housing 11 to form a reference beam 18. The reference laser beam 18 reflects off the interior of the housing 11 within the outgoing chamber 12 to strike a reference array of Single-Photon Avalanche Diodes (SPADs) 20, embedded within a substrate 19. These reference SPADs 20 detect the arrival of the reference beam 18, establishing a reference time-of-flight value. The optical barrier 14 prevents the outgoing beam 17 and reference beam 18 from reaching the incoming chamber 13. The outgoing beam 17 strikes a target, reflects off, and returns as a return beam 23.

The incoming chamber 13 houses an Infrared (IR) notch filter 22, which reduces the amount of ambient light which reaches the return array 21. Once through the IR notch filter 22, the return beam 23 strikes a return array of SPADs 21, also embedded within the substrate 19.

The operation of the dTOF sensor 10 involves a comparison of the time between the reference beam 18 striking the reference array of SPADs 20 and the outgoing beam 17 reaching the target, reflecting back, passing through the IR notch filter 22, and striking the return array of SPADs 21. This time duration is then converted to a distance based on the speed of light, which is constant.

The SPADs 21 are highly sensitive, enabling high time resolution to be achieved by the SPADs 21 and their associated readout circuitry. However, this high sensitivity comes at a cost—the data produced by the SPADs to be used in range calculations involves complex processing performed by digital logic. The digital logic processes the data from the SPADs into meaningful distance metrics, but the complexity involved in this processing results in an increase in power consumption. This is particularly undesirable for battery-operated devices.

To mitigate this, “clock gating” may be employed to help manage the power consumption of the digital logic of the TOF device. Clock gating accomplishes this by turning off or “gating” the clocks provides to certain components of the digital logic when the logic is inactive. As the digital logic consumes a large amount of power, performing the aforementioned clock gating can reduce the average power consumption of the sensor.

Conventionally, clock gating may be implemented by locally disabling the clocks within specific components or blocks during idle periods, or may be implemented via automated tools that detect groups of components that operate in tandem and disables their clocks during idle periods.

The random nature of SPAD events leads to challenges in consistently scheduling the activation and deactivation of clocks. Tool-implemented clock gating, while automated, lacks awareness of the TOF system's operations, and as a result, its power-saving capacity is limited. Given these constraints, there is a need for further development into clock gating techniques.

### SUMMARY

Disclosed herein is a system which includes first digital components clocked by a system clock signal, second digital components clocked by a gated system clock signal, and a detection module configured to detect a detection event and produce an event flag signal upon said detection. The system further includes clock gating circuitry configured to generate a synchronous timing window during which gating of the gated system clock signal is released so that it follows the system clock signal in response to the event flag signal, but to otherwise gate the gated system clock signal such that it does not pulse.

A light source may emit ranging light toward a target, and the clock gating circuitry may be configured to also gate the gated system clock signal when the light source is not activated.

The clock gating circuitry is now described. In particular, a digital comparator is configured to generate a comparator output signal based upon a comparison of a count value with a threshold value, wherein the comparator output signal is asserted by the digital comparator when the count value is less than the threshold value and is deasserted by the digital comparator when the count value is equal to or greater than the threshold value. A counter is configured to set the count value to a pre-determined value upon receipt of the event flag signal, and in response to the comparator output signal being asserted, increment the count value upon each successive rising edge of the system clock signal after the event flag signal is asserted, but to cease incrementing of the count value when the comparator output signal is deasserted. A clock gating module is configured to release gating of the gated system clock signal such that it follows the system clock signal, a first given number of cycles of the system clock signal after assertion of the comparator output signal, and reinstate gating of the gated system clock signal such that it does not pulse, a second given number of cycles of the system clock signal after the release of the gating. The threshold value is equal to the second given number of cycles.

The detection module includes at least one edge detector configured to receive a plurality of detector outputs and assert a corresponding one of a plurality of edge detector outputs in response to an associated one of the plurality of detector outputs indicating detection of the detection event, and a logic circuit configured to assert a first intermediate logic signal in response to assertion of at least one of the plurality of edge detector outputs. The event flag signal is based upon the first intermediate logic signal.

The detection module also includes an AND gate configured to perform a logical AND operation on the first intermediate logic signal and an enable signal to produce the event flag signal.

The logic circuit may be an OR gate.

The clock gating module may include a delay chain configured to delay a version of the comparator output signal by a number of cycles of the system clock signal equal to the first given number of cycles.

The delay chain may include an inverter configured to receive the comparator output signal, a plurality of cascaded flip flops equal to one less than the first given number of cycles, a logic circuit having a first input receiving output from a last of the plurality of cascaded flip flops and a second input receiving the system clock signal, and wherein an output of the logic circuit is the gated system clock signal.

The logic circuit may be an OR gate.

The system may be configured to define a time-of-flight system and further includes a light source configured to emit ranging light toward a target, and a detector configured to detect ranging light that has reflected off the target and returned to the system to generate the detection event.

Also disclosed herein is a method of clocking a system, include clocking first digital components with a system clock signal, clocking second digital components with a gated system clock signal, and detecting a detection event and generating an event flag signal based upon said detection. The method further includes generating a synchronous timing window during which gating of the gated system clock signal is released so that it follows the system clock signal in response to the event flag signal, but otherwise gating the gated system clock signal such that it does not pulse.

The method may further include also gating the gated system clock signal when a light source that emits ranging light toward a target is not activated.

Generating the synchronous timing window is now described, and begins with generating a comparator output signal based upon a comparison of a count value with a threshold value, wherein the comparator output signal is asserted when the count value is less than the threshold value and is deasserted when the count value is equal to or greater than the threshold value. The method further includes setting the count value to a pre-determined value upon receipt of the event flag signal, and in response to the comparator output signal being asserted, incrementing the count value upon each successive rising edge of the system clock signal after the event flag signal is asserted, but cease incrementing of the count value when the comparator output signal is deasserted. The method additionally includes releasing gating of the gated system clock signal such that it follows the system clock signal, a first given number of cycles of the system clock signal after assertion of the comparator output signal, and reinstating gating of the gated system clock signal such that it does not pulse, a second given number of cycles of the system clock signal after the release of the gating. The threshold value is equal to the second given number of cycles.

Detecting the detection event may include receiving a plurality of detector outputs, asserting a corresponding one of a plurality of edge detector outputs in response to an associated one of the plurality of detector outputs indicating the detection of the detection event, and asserting a first intermediate logic signal in response to the assertion of at least one of the plurality of edge detector outputs. The event flag signal may be generated based upon the first intermediate logic signal.

The method may include performing a logical AND operation on the first intermediate logic signal and an enable signal to generate the event flag signal.

Releasing the gating of the gated system clock signal may include delaying a version of the comparator output signal by a number of cycles of the system clock signal equal to the first given number of cycles.

Delaying the version of the comparator output signal may include inverting the comparator output signal, passing the inverted comparator output signal through a series of cascaded flip flops equal to one less than the first given number of cycles, and performing a logical OR operation on an output from the last of the cascaded flip flops with the system clock signal, wherein a result of the logical OR operation provides the gated system clock signal.

The method may be configured to define a time-of-flight system and may further include emitting ranging light toward a target, and detecting ranging light that has reflected off the target and returned to the system to generate the detection event.

### BRIEF DESCRIPTION OF THE DRAWINGS

FIG. 1 is a diagrammatical view of a prior art time of flight sensor.

FIG. 2 is a block diagram of a time-of-flight (TOF) system disclosed herein.

FIG. 3 is a block diagram of the return readout of the TOF system of FIG. 2.

FIG. 4 is a timing diagram of the return readout of FIG. 3 during operation.

FIG. 5 is a block diagram of a generic embodiment of an electronic device utilizing the clock gating scheme implemented by the return readout of the TOF system of FIGS. 2-3.

### DETAILED DESCRIPTION

The following disclosure enables a person skilled in the art to make and use the subject matter described herein. The general principles outlined in this disclosure can be applied to embodiments and applications other than those detailed above without departing from the spirit and scope of this disclosure. It is not intended to limit this disclosure to the embodiments shown, but to accord it the widest scope consistent with the principles and features disclosed or suggested herein.

Disclosed herein is a “look-ahead” clock gating technique. Unlike conventional clock gating techniques, the look ahead system anticipates a TOF event early in the digital data pipeline. Upon identifying the TOF event, the system then synchronously releases clocks to the later stages of the digital logic for a pre-defined period.

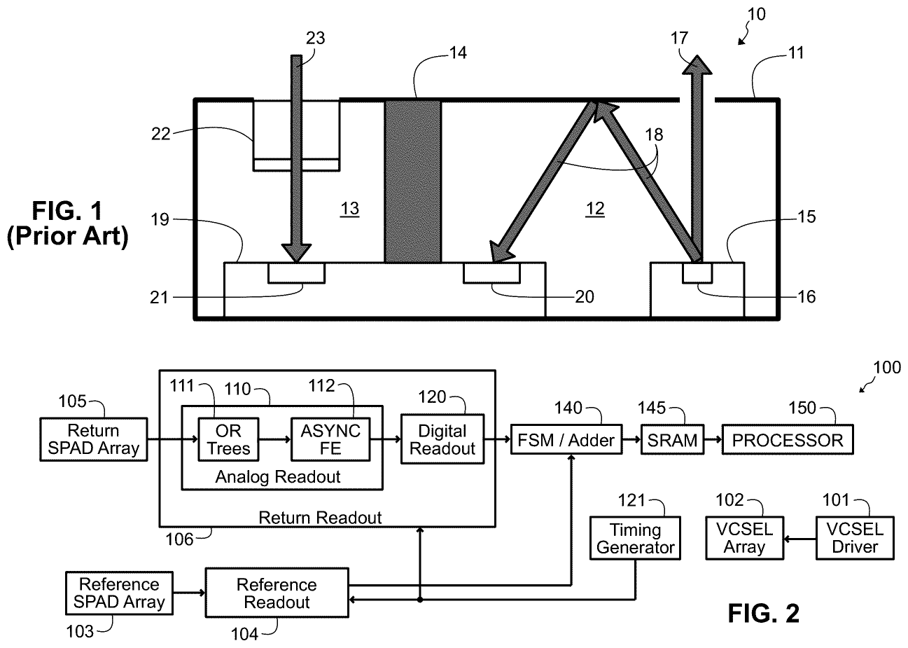

A TOF system 100 incorporating this look-ahead clock gating technique is now described with reference to FIG. 2. The TOF system 100 includes an array of VCSELs 102 driven by a driver 101 during operation to emit pulses of light toward a target, a reference array 103, and a return array 105. The reference array 103 and return array 105 are carried within a housing, with the reference array 103 receiving the portions of the light that bounce off the interior of the housing and the return array 105 receiving the portions of the light that bounce off the target and return. Reference readout circuitry 104 reads out the signals from the reference array 103. Return readout circuitry 106 reads out the signals from the return array 105. The driver 101, reference readout circuitry 104, and return readout circuitry 106 are clocked by clock signals generated by a timing generator 121, such as a phase locked loop (PLL).

The return readout circuitry 106 includes readout circuitry 110 having an asynchronous input, referred to hereinafter as being analog readout circuitry 110 as it is within the analog domain. The return readout circuitry 106 further includes digital readout circuitry 120. The analog readout circuitry 110 includes OR trees 111 connected to receive the outputs of the SPADs of the return array 105, to provide for detection of even faint return light, and an asynchronous front end (AFE) 112 connected to receive the outputs of the OR trees 111. The digital readout circuitry 120 is connected to receive the outputs of the AFE 112. A finite state machine and adder (FSM/ADDER) 140 is connected to receive the outputs of the digital readout circuitry 120 as well as the outputs of the reference readout circuitry 104, and the output of the FSM/ADDER 140 is stored in an SRAM 145.

The operation of the TOF system 100 for distance detection is based on building two separate histograms with respect to an internal timing reference. For the sake of simplicity, consider a single return zone and one reference. A first histogram is built from the reference array 103, which collects the light after it bounces off the interior of the housing. This reference histogram compiles data from thousands to tens of thousands of pulses. Similarly, a return histogram is constructed based on the light that reflects off the target and strikes the return array 105, accumulating data from thousands to tens of thousands of pulses as well.

From these histograms, the pulse phase from the reference histogram is computed, and the pulse phase from the return histogram is also determined.

Subsequently, the difference in these pulse phases is calculated. This difference provides the range information. The FSM portion of the FSM/ADDER 140 manages the process flow and sequences, while the ADDER portion computes the actual pulse phase differences. The resulting computed difference, representing the distance as stated, is stored in the SRAM 145, ready to be accessed by a processor 150 for subsequent processing or actions.

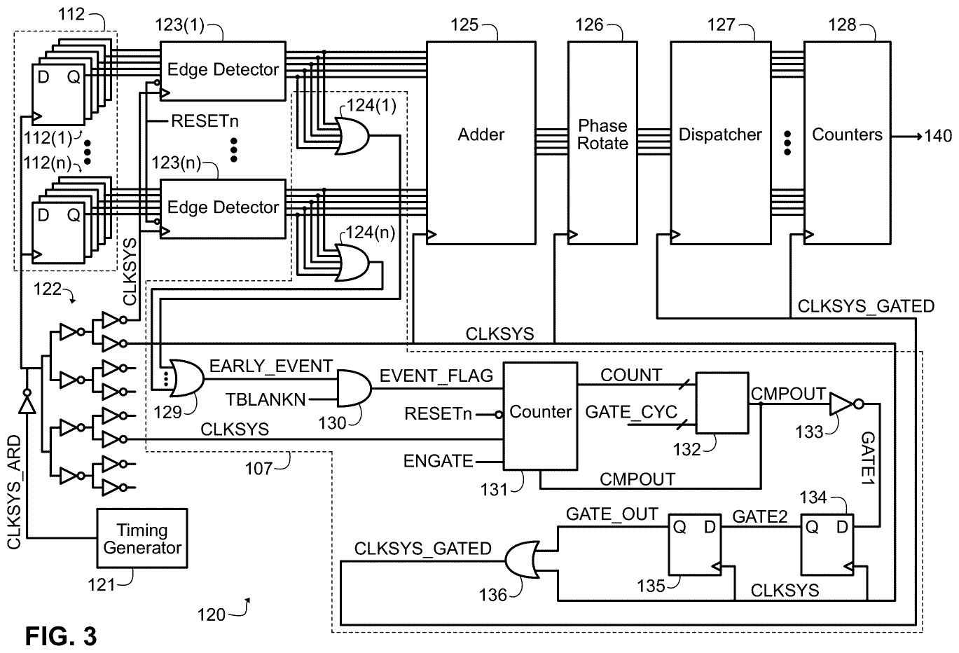

Further details of the digital readout circuitry 120 and the look-ahead clock gating technique are now given with additional reference to FIG. 3. Observe, first, that the AFE 112 includes n rows of flip flops, denoted as 112(1), . . . , 112(n), with each row containing m flip flops. Each of these m flip flops receives output from a distinct OR tree 111 at its data input and stores it for output to the digital readout circuitry 120. With that in mind, the digital readout circuitry 120 includes n edge detectors, denoted as 123(1), . . . , 123(n), each receiving outputs from the m flip flops in their respective rows of flip flops 112(1), . . . , 112(n). The edge detectors 123(1), . . . , 123(n) look for a transition from de-asserted to asserted (e.g., logic low to logic high) in the outputs of the corresponding flip flops 112(1), . . . , 112(n).

An adder 125 receives the outputs from each edge detector 123(1), . . . , 123(n) and serves to add their outputs together to yield a total number of SPAD events detected by each edge detector 123(1), . . . , 123(n) during the current period. A phase rotator 126 receives the outputs of the adder 125 and performs phase rotation thereon to compensate for minor timing errors in the AFE 112. The edge detectors 123(1), . . . , 123(n), adder 125, and phase rotator 126 are clocked by a clock signal CLKSYS generated by passing an analog readout clock CLKSYS_ARD generated by the timing generator 121 through an inverter tree 122, and the edge detectors 123(1), . . . , 123(n) may be reset by assertion of reset signal RESETn.

A dispatcher 127 receives the outputs of the phase rotator 126 and dispatches them into appropriate ones of the counters 128 (a synchronous counter cascaded with a ripple counter) to form a histogram. The dispatcher 127 and counters 128 are clocked by a gated clock signal CLKSYS_GATED generated by clock gating circuitry 107 that performs event-based clock gating on the clock signal CLKSYS.

The clock gating circuitry 107 includes n OR gates, denoted as 124(1), . . . , 124(n), with each OR gate receiving the outputs of a respective one of the n edge detectors 123(1), . . . , 123(n), and provides its output to OR gate 129. The OR gate 129 performs a logical OR operation on its inputs (the outputs of each OR gate 124(1), . . . , 124(n)) to provide the EARLY_EVENT signal. An AND gate 130 receives the EARLY_EVENT signal together with a blanking signal TBLANKN, and performs a logical AND operation thereon to produce the event flag signal EVENT_FLAG. Assuming therefore that the blanking signal TBLANKN is asserted, the combination of the OR gates 124(1), . . . , 124(n) and 129 serves to OR all outputs of the edge detectors 123(1), . . . , 123(n) together so that when any SPAD event occurs (when a SPAD of the return array 105 is struck by an incoming photon originated from the VCSEL array 102 that has bounced off the target), the event flag signal EVENT_FLAG is asserted.

A counter 131 receives the event flag signal EVENT_FLAG, is enabled by the enable signal ENGATE, is reset by the reset signal RESETn, and is incremented by the comparator output CMPOUT. The output of the counter 131 is the count signal COUNT, which is passed to a digital comparator 132.

The operation of the counter 131 is now explained. If the reset signal RESETn is asserted, the count signal COUNT is set to a value of zero. Otherwise, at positive edges of the clock signal CLKSYS:
if the event flag signal EVENT_FLAG is asserted or the enable signal ENGATE is asserted, the count signal COUNT is set to a value of zero;
if the comparator output CMPOUT is asserted (and neither the event flag signal EVENT_FLAG nor the enable signal ENGATE is asserted), the count signal COUNT is incremented, and
if the increment signal INC_CTRL is not asserted (and neither the event flag signal EVENT_FLAG nor the enable signal ENGATE is asserted), the count signal COUNT maintains its current value.

The digital comparator 132 compares COUNT to a gate cycle signal GATE_CYC to produce the comparator output signal CMPOUT, which is passed to counter 131. The digital comparator 132 asserts CMPOUT when the value of COUNT is less than the value of the GATE_CYC; otherwise CMPOUT is not asserted.

The comparator output signal CMPOUT is inverted by inverter 133 to produce the signal GATE1, which is passed to the data input of flip flop 134. Flip flop 134 is clocked by CLKSYS and its output is the signal GATE2, which is passed to the data input of flip flop 135. Flip flop 135 is clocked by CLKSYS and its output is the signal GATE_OUT, which is logically OR'd with CLKSYS by OR gate 135 to produce the gated clock signal CLKSYS_GATED.

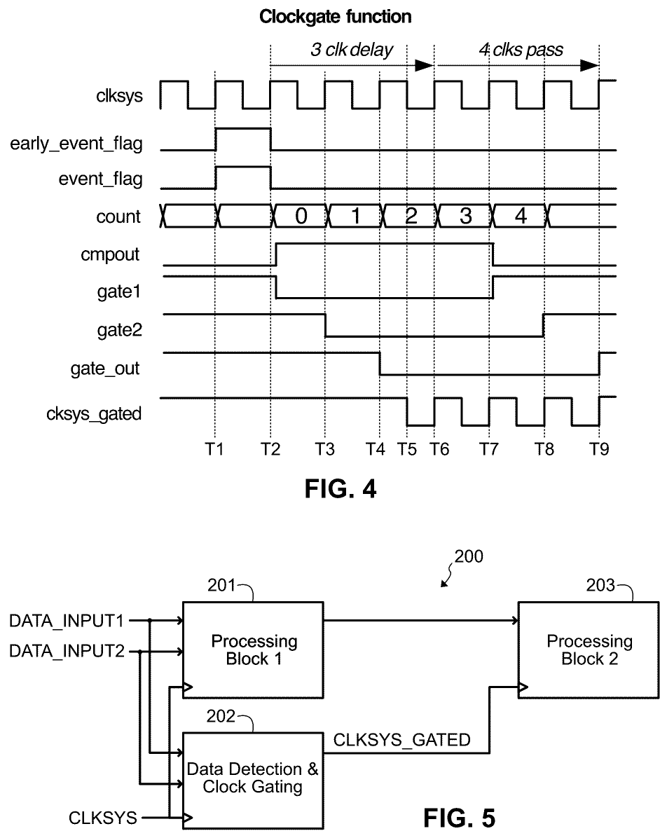

Referring to FIG. 4, the clock gating functionality of the TOF system 100 is now described. Before time T1, no SPAD event is detected, with EVENT_FLAG being deasserted. Both GATE_OUT and CLKSYS_GATED are asserted to save power, ensuring that the dispatcher 127 and counters 128 do not process unnecessary clock cycles.

At the rising edge of CLKSYS at time T1, a SPAD event is detected at the input to the logic within the digital readout circuitry 120. The OR gate 129, in response, asserts EARLY_EVENT, which prompts the AND gate 130 to assert EVENT_FLAG. Given the operational design of counter 131, when EVENT_FLAG is asserted, the counter is set to zero at the next CLKSYS edge. Thus, by the rising edge of CLKSYS at time T2, counter 131 does exactly that, setting COUNT to zero. Since this value is less than GATE_CYC (which is 4 in this example), the digital comparator 132 asserts CMPOUT. Immediately following this, the inverter 133 responds by deasserting GATE1.

By the next rising edge of CLKSYS at time T3, given the assertion of CMPOUT (and with neither EVENT_FLAG nor ENGATE being asserted), the counter 131 increments COUNT to 1 as its operation dictates. With this value still below GATE_CYC, CMPOUT remains asserted. Concurrently, flip flop 134, now clocked by this rising edge, captures the deasserted state of GATE1, leading it to deassert GATE2.

At the next rising edge of CLKSYS at time T4, in response to the continued assertion of CMPOUT and in the absence of assertions of both EVENT_FLAG and ENGATE, counter 131 increments COUNT to 2. This value, still less than GATE_CYC, causes CMPOUT to stay asserted. Concurrently, flip flop 135, clocked by the same edge, deasserts GATE_OUT in response to the deasserted state of GATE2. As a result, CLKSYS_GATED, output by the OR gate 135, starts to mirror CLKSYS, which can be seen the falling edge of CLKSYS at time T5.

By the rising edge of CLKSYS at time T6, given the continued assertion of CMPOUT and the lack of assertion of EVENT_FLAG or ENGATE, counter 131 increments COUNT to 3. This prompts CLKSYS_GATED to align with CLKSYS, marking its own rising edge. From the moment of the assertion of EVENT_FLAG at time T2 to this point, three cycles of CLKSYS have elapsed. This clock gating is designed for power efficiency, activating the dispatcher 127 and counters 128 only after a three-cycle delay following SPAD event detection, at which point the output from the phase rotator 126 is expected to be needed.

At the rising edge of CLKSYS at time T7, in response to the assertion of CMPOUT and the lack of assertion of both EVENT_FLAG and ENGATE, counter 131 increments COUNT to 4. This value, now being equal to GATE_CYC, causes the digital comparator 132 to deassert CMPOUT. Responding to this, the inverter 133 asserts GATE1. This has not yet propagated to GATE2 or GATE_OUT, allowing CLKSYS_GATED to continue its synchronization with CLKSYS at this point.

By the rising edge of CLKSYS at time T8, flip flop 134, acting upon this clock pulse, captures the asserted state of GATE1, and in turn, asserts GATE2. Consequently, by the next rising edge of CLKSYS at time T9, flip flop 135, clocked by the edge, asserts GATE_OUT, reinstating the clock gating for CLKSYS_GATED. This operation sees that the dispatcher 127 and counters 128 function only when needed to process the output of the phase rotator 126.

In summary, from times T6 to T9, four CLKSYS_GATED pulses are generated. This gated clocking approach serves the objective of increasing power efficiency. The clock gating mechanism is deliberately designed to provide so that the dispatcher 127 and counters 128 are clocked only during the specific intervals when the output from the phase rotator 126, resulting from a detected SPAD event, is anticipated to be received. By doing so, these components process the relevant data. Outside of these periods, the clock to the dispatcher 127 and counters 128 is gated, thereby substantially curtailing power consumption. This dual functionality provides so that the system 100 remains responsive to SPAD events while also being energy-efficient during periods of inactivity.

Finally, it is evident that modifications and variations can be made to what has been described and illustrated herein without departing from the scope of this disclosure. For example, see the digital device 200 shown in FIG. 5, which serves as a generalized embodiment. Unlike the TOF system 100 which is specialized for time-of-flight measurements, device 200 shows how the clock gating techniques described herein can be applied in other applications. Within device 200, a processing block 201 receives at one or more digital input signals, in this example being DATA_INPUT1 and DATA_INPUT2. A data detection and clock gating block 202 also receives the DATA_INPUT1 and DATA_INPUT signals. Blocks 201 and 202 are clocked by CLKSYS. Utilizing the clock gating techniques of the TOF system 100, block 202 dynamically outputs a clock signal CLKSYS_GATED. The modulation and progression of CLKSYS_GATED are governed by the detection of events from either the DATA_INPUT1 signal or the DATA_INPUT2. Upon an event, after a first given number of cycles of CLKSYS, Block 202 briefly releases the gating on CLKSYS_GATED, allowing it to follow CLKSYS for a second given number of cycles. Another processing block 203 is clocked by CLKSYS_GATED and processes the results from block 201. Digital device 200 therefore illustrates that the clock gating techniques utilized in TOF system 100 are usable outside of time-of-flight applications.

Although this disclosure has been described with a limited number of embodiments, those skilled in the art, having the benefit of this disclosure, can envision other embodiments that do not deviate from the disclosed scope. Furthermore, skilled persons can envision embodiments that represent various combinations of the embodiments disclosed herein made in various ways.

1. A system, comprising:
first digital components clocked by a system clock signal;
second digital components clocked by a gated system clock signal;
a detection module configured to detect a detection event and produce an event flag signal upon said detection; and
clock gating circuitry configured to generate a synchronous timing window during which gating of the gated system clock signal is released so that it follows the system clock signal in response to the event flag signal, but to otherwise gate the gated system clock signal such that it does not pulse.

2. The system of claim 1, further comprising a light source configured to emit ranging light toward a target; and wherein the clock gating circuitry is configured to also gate the gated system clock signal when the light source is not activated.

3. The system of claim 1, wherein the clock gating circuitry comprises:
a digital comparator configured to generate a comparator output signal based upon a comparison of a count value with a threshold value, wherein the comparator output signal is asserted by the digital comparator when the count value is less than the threshold value and is deasserted by the digital comparator when the count value is equal to or greater than the threshold value;
a counter configured to:
set the count value to a pre-determined value upon receipt of the event flag signal; and
in response to the comparator output signal being asserted, increment the count value upon each successive rising edge of the system clock signal after the event flag signal is asserted, but to cease incrementing of the count value when the comparator output signal is deasserted; and
a clock gating module configured to:
release gating of the gated system clock signal such that it follows the system clock signal, a first given number of cycles of the system clock signal after assertion of the comparator output signal; and
reinstate gating of the gated system clock signal such that it does not pulse, a second given number of cycles of the system clock signal after the release of the gating;
wherein the threshold value is equal to the second given number of cycles.

4. The system of claim 3, wherein the detection module comprises:
at least one edge detector configured to receive a plurality of detector outputs and assert a corresponding one of a plurality of edge detector outputs in response to an associated one of the plurality of detector outputs indicating detection of the detection event; and
a logic circuit configured to assert a first intermediate logic signal in response to assertion of at least one of the plurality of edge detector outputs;
wherein the event flag signal is based upon the first intermediate logic signal.

5. The system of claim 4, wherein the detection module further comprises an AND gate configured to perform a logical AND operation on the first intermediate logic signal and an enable signal to produce the event flag signal.

6. The system of claim 4, wherein the logic circuit comprises an OR gate.

7. The system of claim 4, wherein the clock gating module comprises:
a delay chain configured to delay a version of the comparator output signal by a number of cycles of the system clock signal equal to the first given number of cycles.

8. The system of claim 7, wherein the delay chain comprises:
an inverter configured to receive the comparator output signal;
a plurality of cascaded flip flops equal to one less than the first given number of cycles; and
a logic circuit having a first input receiving output from a last of the plurality of cascaded flip flops and a second input receiving the system clock signal;
wherein an output of the logic circuit is the gated system clock signal.

9. The system of claim 8, wherein the logic circuit comprises an OR gate.

10. The system of claim 1, wherein the system is configured to define a time-of-flight system and further comprises:
a light source configured to emit ranging light toward a target; and
a detector configured to detect ranging light that has reflected off the target and returned to the system to generate the detection event.

11. A method of clocking a system, comprising:
clocking first digital components with a system clock signal;
clocking second digital components with a gated system clock signal;
detecting a detection event and generating an event flag signal based upon said detection; and
generating a synchronous timing window during which gating of the gated system clock signal is released so that it follows the system clock signal in response to the event flag signal, but otherwise gating the gated system clock signal such that it does not pulse.

12. The method of claim 11, further comprising also gating the gated system clock signal when a light source that emits ranging light toward a target is not activated.

13. The method of claim 11, wherein generating the synchronous timing window comprises:
generating a comparator output signal based upon a comparison of a count value with a threshold value, wherein the comparator output signal is asserted when the count value is less than the threshold value and is deasserted when the count value is equal to or greater than the threshold value;
setting the count value to a pre-determined value upon receipt of the event flag signal;
in response to the comparator output signal being asserted, incrementing the count value upon each successive rising edge of the system clock signal after the event flag signal is asserted, but cease incrementing of the count value when the comparator output signal is deasserted;
releasing gating of the gated system clock signal such that it follows the system clock signal, a first given number of cycles of the system clock signal after assertion of the comparator output signal; and
reinstating gating of the gated system clock signal such that it does not pulse, a second given number of cycles of the system clock signal after the release of the gating;
wherein the threshold value is equal to the second given number of cycles.

14. The method of claim 13, wherein detecting the detection event comprises: receiving a plurality of detector outputs; asserting a corresponding one of a plurality of edge detector outputs in response to an associated one of the plurality of detector outputs indicating the detection of the detection event; and asserting a first intermediate logic signal in response to the assertion of at least one of the plurality of edge detector outputs; wherein the event flag signal is generated based upon the first intermediate logic signal.

15. The method of claim 14, further comprising performing a logical AND operation on the first intermediate logic signal and an enable signal to generate the event flag signal.

16. The method of claim 13, wherein releasing the gating of the gated system clock signal comprises: delaying a version of the comparator output signal by a number of cycles of the system clock signal equal to the first given number of cycles.

17. The method of claim 16, wherein delaying the version of the comparator output signal comprises:
inverting the comparator output signal;
passing the inverted comparator output signal through a series of cascaded flip flops equal to one less than the first given number of cycles; and
performing a logical OR operation on an output from a last of the cascaded flip flops with the system clock signal, wherein a result of the logical OR operation provides the gated system clock signal.

18. The method of claim 13, wherein the method is configured to define a time-of-flight system and further comprises:
emitting ranging light toward a target; and
detecting ranging light that has reflected off the target and returned to the system to generate the detection event.
